(19) United States
(12) Patent Application Publication
(10) Pub. No.: US 2023/0125041 A1
(43) Pub. Date: Apr. 20, 2023

(54) MEMORY CHIP STACK FOR HIGH PERFORMANCE LOGIC CHIPS

(71) Applicant: Intel Corporation, Santa Clara, CA (US)

(72) Inventors: Christopher P. MOZAK, Portland, OR (US); Sagar SUTHRAM, Portland, OR (US); Randy B. OSBORNE, Beaverton, OR (US); Don Douglas JOSEPHSON, Fort Collins, CO (US); Surhud KHARE, Buffalo, NY (US)

(21) Appl. No.: 18/086,584

(22) Filed: Dec. 21, 2022

(51) Int. Cl. H10B 80/00; G11C 11/408; H01L 23/528; G06F 12/06

(52) U.S. Cl. CPC H10B 80/00; G11C 11/4087; H01L 23/5286; G06F 12/0607; H01L 24/16

(57) ABSTRACT

A memory chip stack is described. The memory chip stack includes memory chips having a first plurality of memory channels, where non-yielding ones of the memory channels are to be disabled during operation of the memory chip stack. The first plurality of memory channels have a second plurality of memory banks, where non-yielding ones of the memory banks within yielding ones of the memory channels are to be disabled during the operation of the memory chip stack.

### BACKGROUND OF THE INVENTION

The continued reduction of transistor minimum feature size has resulted in tremendous numbers of transistors being integrated on a single logic chip. As a consequence, logic chip computational ability is reaching extremely high levels (e.g., as demonstrated by artificial intelligence implementations). Generally, logic chip computations use memory as a data scratch pad, data store and/or instruction store (for those logic chips that execute instructions in the case of the later). As logic chip computational ability continues to expand, the bandwidth and storage capacity of the memory used to support logic chip operation will likewise need to expand.

### BRIEF DESCRIPTION OF DRAWINGS

FIG. 1 shows a memory chip stack;

FIG. 2 shows a memory chip stack design architecture;

FIG. 3 shows an improved memory chip stack design architecture;

FIG. 4 shows an improved memory interleaving process;

FIG. 5 shows a computing system.

### DETAILED DESCRIPTION

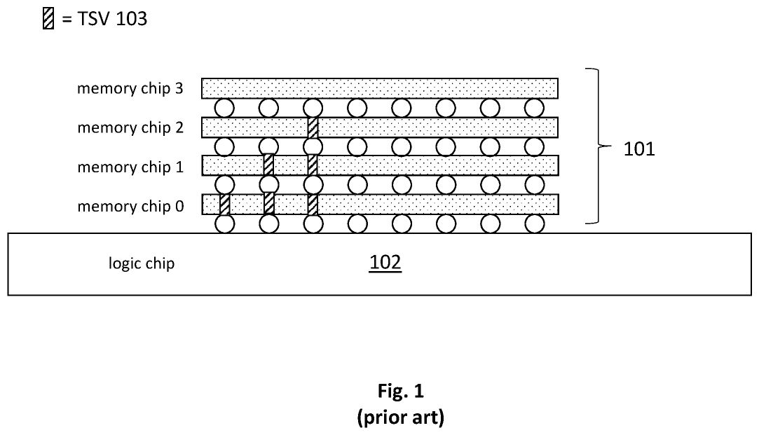

One approach to increase both memory storage capacity and reduce memory access time delay, referring to FIG. 1, is to stack memory chips 101 on top of a logic chip 102 that uses the memory chips 101 to service the logic chip's computational functions. Here, the presence of a stack of memory chips 101 on the surface of the logic chip 102 provides large scale memory capacity for the logic chip 102 because the memory cells are arranged in three dimensions (rather than two dimensions as with, e.g., traditional dual-in line memory modules (DIMMs)). Additionally, the logic chip 102 will enjoy lower memory access times (as compared to external memory such as, again, DIMM technology) because the wiring distance between the logic chip 102 and the memory 101 is minimized. This, in turn, reduces the wiring's parasitic capacitances and/or resistances and allows for very high frequency signals to be passed between the logic chip 102 and the memory chips 101.

The stacked memory chip 101 solution therefore provides the high capacity and high bandwidth memory resources that the logic chip 102 needs. As observed in FIG. 1, the wiring between the logic chip 102 and a specific memory die in the stack is affected with through silicon vias (TSVs) 103 that run through the memory chips 101 (for ease of drawing only one TSV is depicted for each of the second, third and fourth memory chip in the stack 101 (memory chips 1, 2 and 3)). The logic chip 102 may connect to the package substrate (not shown) through the DRAM (package substrate on top in FIG. 1), around the DRAM (package substrate on top in FIG. 1) or through its own TSVs (package substrate on bottom in FIG. 1) or some combination of these approaches.

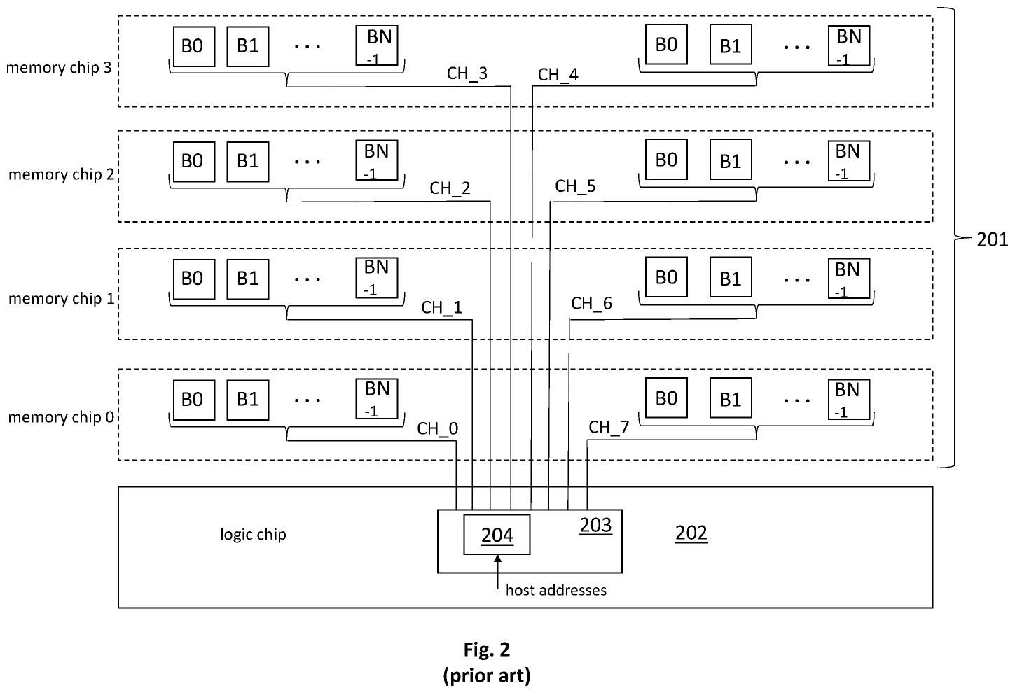

FIG. 2 shows a typical design architecture for a stacked memory solution 201. In particular, FIG. 2 shows the traditional architecture of the memory chips used in a stacked memory implementation. Here, banks of memory resources on single memory chip die are partitioned into different groups and each group is viewed as a different channel. In the specific example of FIG. 2, each memory chip die supports two channels, where each channel includes N memory banks (banks B0 through B(N−1)). Thus, with four memory chips in the stack, there are eight different channels in the total solution (CH_0 through CH_7). The logic chip 202 can read from and/or write to the respective memory banks of any channel independently of (and concurrently with) the chip's accessing of the other channels. Thus, each channel has its own dedicated data and address lines.

To further enhance the overall bandwidth of the memory chip stack 201 as observed by the underlying logic chip 202, in the case where the memory chips in the stack 201 are dynamic random access memory (DRAM) chips, memory address interleaving can be utilized to reduce the impact of access time delays associated with page misses. Here, the memory resources within a bank of DRAM memory are partitioned into smaller pages. Generally, only one of the pages in a bank of memory is “active” at any moment in time. If an access to a memory bank is not directed to the active page, a penalty will be incurred waiting for the page that is targeted by the access to become the bank's new active page.

Memory address interleaving attempts to spread consecutive host memory accesses across different banks to obtain more observed memory bandwidth from the perspective of the host. Here, a host address will often target a different bank than its immediately preceding address, in which case, the consecutive accesses will be directed to different banks (rather than the same bank with a potential page miss occurring at each address).

As such, as observed in FIG. 2, the logic chip 202 includes decoder circuitry 203 that, converts host memory addresses generated internally by the logic chip into memory stack addresses that target a particular bank within a particular channel within a particular memory chip in the memory chip stack. The decoder 203 includes interleaving circuitry 204 to interleave the host memory addresses so that numerically consecutive host addresses (e.g., XXXXX0000 and XXXXX0001) map to different channels.

According to another interleaving approach, consecutive host memory addresses are interleaved across the N banks within the same channel. That is, for example, the first address in the block is mapped to bank 0 (B0), the second (next consecutive) address is mapped to bank 1 (B1), etc. The mapping continues to map a next consecutive address to a next bank. When the Nth bank is reached (BN−1), the next consecutive address maps back to bank 0 (B0) and the process repeats.

According to a third approach, consecutive host addresses are interleaved across bank groups.

Going forward for future high performance logic chips, the memory chips' physical width and/or length dimensions will need to become larger to expand memory chip storage capacity (more storage cells per memory chip) to properly serve the memory needs of the underlying logic chip. Thus, whereas only two channels exist per memory chip in the traditional stacked memory chip solution example of FIG. 2 (which is consistent with the Joint Electron Device Engineering Council (JEDEC) High Bandwith Memory 2 (HBM2) standard, JESD235A published 2016), and whereas, the industry's current leading edge stacked memory chip solution (described by the JEDEC HBM3 standard JESD238 published 2022) describes a memory stack solution having four channels per memory chip die, by contrast, the much larger memory die of future memory chip stacks could support 64, 128, 256, etc. channels per memory chip die.

Forming memory stacks with such large memory chips raises a number of issues. A first issue is the occurrence of manufacturing defects within the individual memory chips themselves. Here, as storage cell sizes continue to shrink with each next memory chip manufacturing technology, manufacturing defects are become more prevalent. Memory chip suppliers have addressed this concern by incorporating extra (“spare”) rows and/or columns in their storage cell arrays. During manufacturing of a memory chip, the supplier tests the storage cell arrays on their respective memory chips. If a particular row or column of an array has a defective cell, the manufacturer enables a spare row or column in the same array to take its place.

Additionally, soft bit errors are becoming more prevalent even in working cells. As such memory chip suppliers have also designed error correction coding (ECC) circuitry into their memory chips so that a soft error in a memory read can be corrected before the read data is provided to the requesting host system.

With respect to memory chips used for present day (e.g., HBM2, HBM3) memory chips, however, no redundancy is implemented on a per channel basis. This is mostly a consequence of the relatively small die dimensions that only support two (HBM2) or four (HBM2) channels per die.

For much larger memory chips having, e.g., 64 or more channels per die, however, not having bank or channel redundancy could result in manufactured stacks of memory chips with extremely low product yields. Here, wafer to wafer (W2 W) bonding is typically used to form memory chip stacks. In the case of wafer to wafer bonding, an entire first wafer of memory chips is bonded to an entire second wafer of memory chips with, e.g., micro solder bumps (or hybrid bonding) positioned at the interface between aligned chips on different wafers. For a four chip stack, a third wafer is similarly bonded to the two wafer stack and then a fourth wafer is bonded to the three wafer stack. The stack of four bonded wafers is then diced along memory chip boundary lines to create separate individual “four high” stacks of memory chips.

The aforementioned micro solder bump technology used to bond wafers as described above generally do not yield at 100%. Instead, some appreciable percentage of such micro bumps are either electrical opens (do not make the desired electrical connection), electrical shorts (such as a ground-power shorts) and/or damage other electrical I/O structures at the surfaces of the memory chips (such as the TSVs).

Additionally, beyond the micro-bump yield loss, wafer to wafer stacking does not allow dies to first be tested and only good dies assembled into a package. The entire wafer, including good and bad dies, is stacked on another wafer. If any die in the N high stack is bad, then entire stack is bad without redundancy or repair.

Because these types of defects are external from the memory chips themselves, they cannot be recovered from with spare memory array rows/columns or with ECC. As such, micro bump defects can render a channel they are associated with as non-functional (the entire channel is bad). For current HBM memory stacks having only two or four channels per memory chip die, the micro bump defect rate is tolerable because the smaller HBM die translates into many more chip stacks per set of bonded wafers. Essentially, a small number of such stacks do not yield because of the external micro-bump defects but many more stacks from the same wafer stack yield successfully.

If the size of the memory chip is dramatically increased, however, the yield dynamics drastically change. Here, it could be likely that there is at least one bad channel per stack of large memory die resulting in near zero yield of stacked memory chip product from a set of bonded wafers.

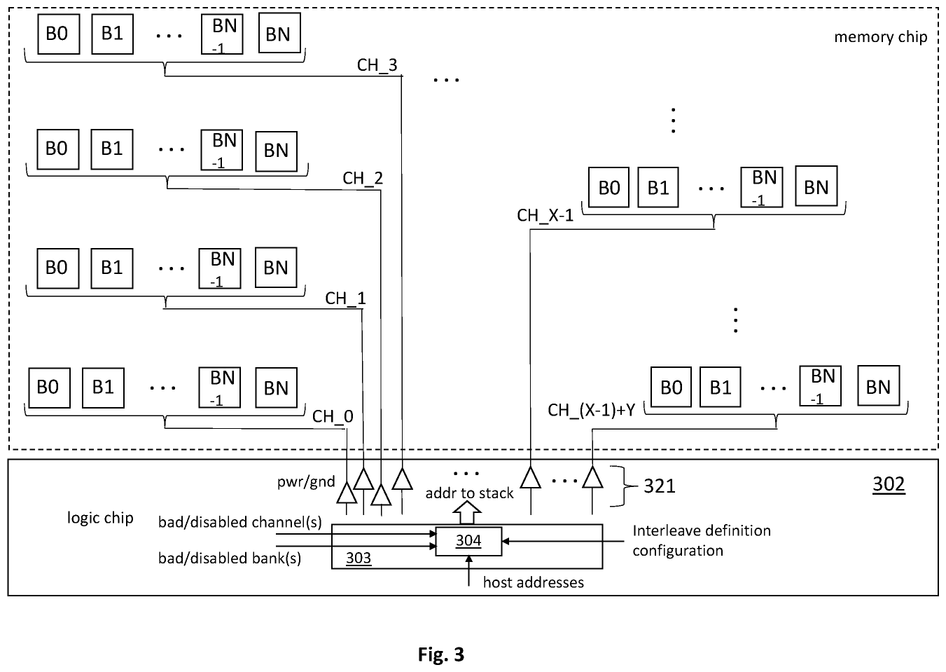

FIG. 3 depicts a future generation memory stack solution that includes channel redundancy in order to address the yield concerns described just above (for ease of illustration only one memory chip in the stack is depicted in FIG. 3). For example, in an embodiment, the memory chip stack is designed to have X working channels per memory chip and NX working channels total per stack (where N is the number of chips in the stack).

However, the memory chips themselves are each designed to include Y channels where Y>X. Thus, for any memory chip in the stack, if any of the memory chip's Y channels are damaged, such channels are not enabled, and only working (non damaged) channels are enabled. So long as the number of working channels on the memory chip is X or greater the memory chip will not cause a yield failure for the overall stack. As just one example, if Y=72 (e.g., an 8×9 array of channels are designed into the memory chip) and X=64, up to eight channels can be damaged on a memory chip without causing a yield failure to the stack that the memory chip is a component of.

Additionally, as observed in FIG. 3, each of the channels includes a redundant bank (bank BN). Here, if a bank within a channel does not yield (e.g., due to internal defects of the memory chip or external defects that, for whatever reason, only affected the non yielding bank), the non working bank is disabled but there remains enough working channels in the bank (N) to deem the channel a working channel (here, e.g., the architecture of the memory system assumes N working banks per channel). For ease of drawing FIG. 3 only shows one redundant bank per channel. However, in other implementations there can be more than one redundant bank per channel (e.g., two, three, four, etc.) to better preserve channel yield in the face of bank fallout.

In various embodiments, the interleaving circuitry 304 within the decoder 303 is designed to implement memory interleaving in view of any channels and/or banks that have not yielded or have otherwise been disabled. That is, unlike the traditional interleaving logic 204 of FIG. 2, the improved interleaving circuitry 304 includes additional input information that identifies which channels are not to be mapped to (and/or are to be mapped to) and which banks within the working channels are not to be mapped to (and/or are to be mapped to).

Such interleaving circuitry 304 can therefore include or rely on state elements (e.g., register space, static random access memory (SRAM) and/or embedded DRAM (eDRAM) on the logic die 302) that record information describing which channels and which banks within working channels are to be mapped to (and/or the inverse describing which channels are not be mapped to and which banks within working channels are not to be mapped to). The internal logic of the interleaving circuitry 304 uses this information, e.g., as input terms to a mathematical relationship that the circuitry 304 executes with logic circuitry to determine a next address, and/or circuitry that builds a look-up table that defines which host addresses map to which channel and bank addresses in the memory stack.

Such interleaving circuitry 304 can be designed to implement the interleave in a hierarchal fashion for better scalability. For example, the interleave may first be done at a coarse level that directs traffic to one of 4 quadrants on the logic die 303, 304. Then within each quadrant a finer interleave is performed on the logic die 303, 304 for all channels/banks in that quadrant.

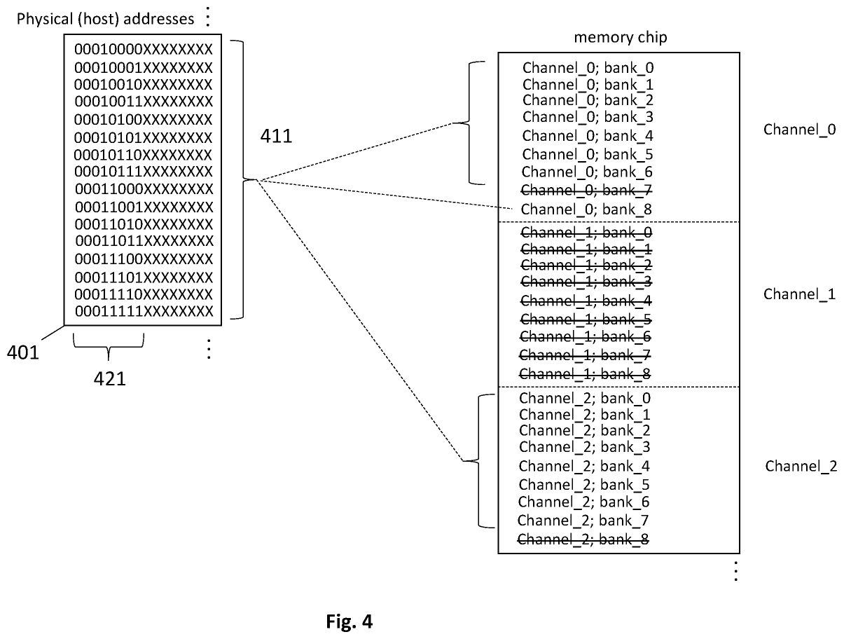

FIG. 4 shows a high level view of an interleaving process that takes account of both channel redundancy and bank redundancy. In the example of FIG. 4, the decoder's interleaving circuitry is configured to interleave a block of host addresses 411 across the respective memory banks of multiple channels. The example assumes that a working channel has eight working banks and each channel has nine banks (one extra bank of redundancy per channel).

As observed in FIG. 4, memory bank 7 of channel_0 did not yield. As such, bank 8 of channel_0 was enabled to take the place of bank 7 (which is disabled). Additionally, channel_1 did not yield. Within channel_2, all banks yielded thus redundant bank 8 in channel_2 is disabled. As such, as observed in FIG. 4, the interleaving circuitry is configured to implement an interleaving process that maps host addresses 411 across banks 0 though 6 and 8 of channel_0, and, banks 0 through 7 of channel_1. Channel_1 is skipped over in the interleave mapping. Here, the interleaving circuitry 304 is provided information that describes which channels/banks yielded or do not yield and sets up an internal math equation and/or look-up table to affect the correct interleave mapping in view of this information.

In various embodiments, the interleaving logic 304 can interleave according to any of a number of different memory address block definitions and corresponding memory resource boundary scheme. For example, according to a first approach, host addresses are interleaved within a channel but not across channels (consecutive host addresses are only spread across banks in a same channel).

According to a second approach, host addresses are interleaved across channels. Here, depending on implementation, the number of channels within a same interleaving group can be: 1) some number that is less than all of the channels on a memory chip (e.g., if the memory chip has 64 channels, the banks within a same interleaving group are spread across 8 channels, 16 channels, etc.); 2) all of the channels on a memory chip but no other memory chip in the stack; 3) multiple channels across multiple chips (e.g., a subset of channels on each of multiple chips, all channels on each of multiple chips, etc.).

In various embodiments, the decoder is designed to be configurable so that the decoder can be configured to implement any of the interleaving possibilities described above (lowest ordered address bits interleaving across channels, across banks, across bank groups, etc.). Here, generally, as the set of banks within a same interleaving group expands to include more and more memory channels, the bandwidth of the memory as experienced by the logic chip increases at the expense of consumed electrical power (because a channel can be accessed independently of other channels and concurrently accessed with other channels). As such, the interleaving circuitry 304 in the improved decoder 303 includes input(s) to receive configuration information that defines the specific interleaving approach to be applied.

In further embodiments, referring to FIG. 3, the memory chips in the stack are designed with dedicated power and ground nodes per channel. That is, each channel of each memory chip has its own dedicated set of power and ground nodes that appear as micro bumps on the memory chip's surface. Such power/ground nodes are electrically isolated from the dedicated power/ground nodes of the other channels on the same memory chip.

Additionally, the logic chip 302 is designed to provide power to the chip stack and includes separate power and ground supply circuitry 321 (e.g., gates and/or drivers) for individual channels 321 per memory chip. Each instance of supply circuitry for a particular channel is electrically isolated from the power and ground supply circuitry that provides power and ground for other channels. As such, if the power and/or ground nodes for any particular channel do not yield during chip stack manufacturing, only the particular channel is rendered “bad” and no other channels on the same chip or other chips in the stack are affected.

In alternative embodiments, e.g., to decrease the TSVs and/or chip-to-chip I/O, a limited group of channels on a same memory chip are coupled to a same power/ground island that is supplied by an instance of power/ground supply circuitry on the logic chip 302. For example, if a memory chip has 64 channels there are 16 separate power/ground islands that each supply a set of 4 channels. If a manufacturing defect affects one of the islands all four channels in the island are disabled, but the remaining channels on the other islands are not affected by the manufacturing defect. In various embodiments there can be two four, eight, twelve, etc. memory channels per same power/ground island on a same memory chip.

Embodiments above have indicated that there can be a standard number of working channels per memory chip die (e.g., X as described above) and banks per channel, (e.g., N as described above). That is, manufactured memory stacks are defined to have a specific number of working channels memory per memory chip die (X) and specific number of working channels per die (N) —no more and no less.

In alternate approaches these numbers can be flexible, e.g., to take advantage of all the working memory resources that yield through manufacturing. For example, considering a memory chip that has a total of Y manufactured channels, if Y channels yield, then all Y channels are enabled (the number of working memory channels is not reduced to X).

Similarly, memory channels are configured to enable as many banks that survive manufacturing rather than focus on enabling only a specific number of banks. For example, some minimum number of banks need to yield to consider the memory channel a working memory channel, where all banks above the minimum number are enabled. For example, if a memory channel is designed to have ten banks and a minimum of eight banks are needed to deem the memory channel a working memory channel, the memory channel will be configured to with eight, nine or ten enabled banks respectively depending on whether eight, nine or ten banks yield.

This type of usage can also be important if an application ideally wants a maximum number of available banks (e.g., 16 banks). Here, if N=16 in FIG. 3, adding the 17^{th} bank for redundancy can be inefficient in terms of silicon area utilization (it is difficult to arrange 17 identical blocks in a rectangular box). For this style of interleaving, one option would be to implement N=15 (=16 total banks), interleave N−1 (15) banks across all channels and then interleave the Nth (16^{th}) bank across only those channels where all 16 banks yielded.

In various embodiments the interleaving circuitry 304 is designed to accommodate varying numbers of working channels and banks per manufactured memory stack product. That is, the interleaving circuitry 304 is informed of how many memory channels are working on each memory die and how many banks are working within each memory channel and internally configures a customized interleaving scheme for the particular memory stack that it is coupled to and that yielded, e.g., its own unique combination of working channels and working banks.

The logic chip 302 can include any of number of high performance logic units such as general purpose processing cores, graphics processing cores, computational accelerators, machine learning cores, inference engine cores, image processing cores, infrastructure processing unit (IPU) core, etc.

In various embodiments, the interleaving circuitry 304 is designed to carefully consider complexity where higher complexity may provide additional DRAM recovery but comes at the cost of additional memory latency from the host perspective due to complex decoding. Grouping channel or banks with similar characteristics (e.g., group all channels that yielded all N banks) together can help reduce this complexity.

The interleaving circuitry can be constructed from any/all of state machine logic circuitry (e.g., dedicated/custom hard-wired logic circuitry), programmable logic circuitry (such as field programmable gate array (FPGA) logic circuitry), and logic circuitry that executes program code to implement at least some of the interleaving circuitry's functions (e.g., such as micro-controller circuitry).

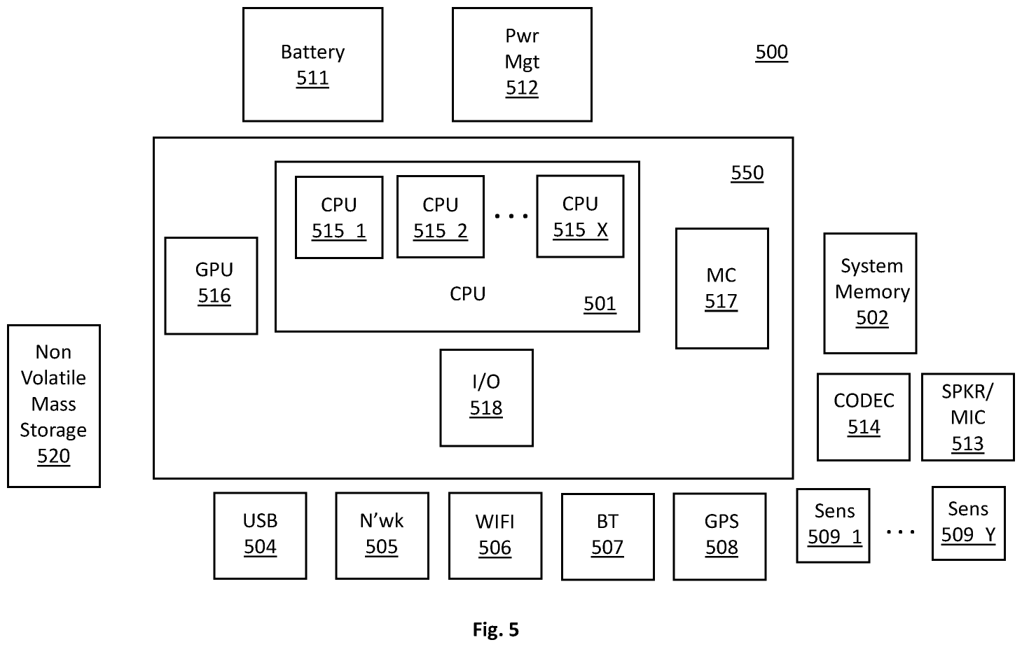

The logic chip and stacked memory solution can be integrated into various electronic systems such as a computing system. FIG. 5 depicts a basic computing system. The basic computing system 500 can include a central processing unit (CPU) 501 (which may include, e.g., a plurality of general purpose processing cores 515_1 through 515_X) and a main memory controller 517 disposed on a multi-core processor or applications processor, main memory 502 (also referred to as “system memory”), a display 503 (e.g., touchscreen, flat-panel), a local wired point-to-point link (e.g., universal serial bus (USB)) interface 504, a peripheral control hub (PCH) 518; various network I/O functions 505 (such as an Ethernet interface and/or cellular modem subsystem), a wireless local area network (e.g., WiFi) interface 506, a wireless point-to-point link (e.g., Bluetooth) interface 507 and a Global Positioning System interface 508, various sensors 509_1 through 509_Y, one or more cameras 510, a battery 511, a power management control unit 512, a speaker and microphone 513 and an audio coder/decoder 514.

An applications processor or multi-core processor 550 may include one or more general purpose processing cores 515 within its CPU 501, one or more graphical processing units 516, a main memory controller 517 and a peripheral control hub (PCH) 518 (also referred to as I/O controller and the like). The general purpose processing cores 515 typically execute the operating system and application software of the computing system. The graphics processing unit 516 typically executes graphics intensive functions to, e.g., generate graphics information that is presented on the display 503. The main memory controller 517 interfaces with the main memory 502 to write/read data to/from main memory 502. The power management control unit 512 generally controls the power consumption of the system 500. The peripheral control hub 518 manages communications between the computer's processors and memory and the I/O (peripheral) devices.

Other high performance functions such as computational accelerators, machine learning cores, inference engine cores, image processing cores, infrastructure processing unit (IPU) core, etc. can also be integrated into the computing system.

Each of the touchscreen display 503, the communication interfaces 504-507, the GPS interface 508, the sensors 509, the camera(s) 510, and the speaker/microphone codec 513, 514 all can be viewed as various forms of I/O (input and/or output) relative to the overall computing system including, where appropriate, an integrated peripheral device as well (e.g., the one or more cameras 510). Depending on implementation, various ones of these I/O components may be integrated on the applications processor/multi-core processor 550 or may be located off the die or outside the package of the applications processor/multi-core processor 550. The computing system also includes non-volatile mass storage 520 which may be the mass storage component of the system which may be composed of one or more non-volatile mass storage devices (e.g., hard disk drive, solid state drive, etc.). The non-volatile mass storage 520 may be implemented with any of solid state drives (SSDs), hard disk drive (HDDs), etc.

Embodiments of the invention may include various processes as set forth above. The processes may be embodied in program code (e.g., machine-executable instructions). The program code, when processed, causes a general-purpose or special-purpose processor to perform the program code's processes. Alternatively, these processes may be performed by specific/custom hardware components that contain hard wired interconnected logic circuitry (e.g., application specific integrated circuit (ASIC) logic circuitry) or programmable logic circuitry (e.g., field programmable gate array (FPGA) logic circuitry, programmable logic device (PLD) logic circuitry) for performing the processes, or by any combination of program code and logic circuitry.

Elements of the present invention may also be provided as a machine-readable medium for storing the program code. The machine-readable medium can include, but is not limited to, floppy diskettes, optical disks, CD-ROMs, and magneto-optical disks, FLASH memory, ROMs, RAMs, EPROMs, EEPROMs, magnetic or optical cards or other type of media/machine-readable medium suitable for storing electronic instructions.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

1. An apparatus, comprising:
a memory chip stack comprising memory chips having a first plurality of memory channels, where, non-yielding ones of the memory channels are to be disabled during operation of the memory chip stack, wherein, the first plurality of memory channels have a second plurality of memory banks, where non-yielding ones of the memory banks within yielding ones of the memory channels are to be disabled during the operation of the memory chip stack.

2. The apparatus of claim 1 wherein yielding ones of the memory channels are to be disabled so that there is a predetermined number of working memory channels on each of the memory chips.

3. The apparatus of claim 1 wherein yielding ones of the memory banks are to be disabled so that there is a predetermined number of working memory banks in each of the memory channels.

4. The apparatus of claim 1 wherein all yielding ones of the memory channels are to be enabled.

5. The apparatus of claim 4 wherein all yielding banks of the yielded memory channels are to be enabled.

6. The apparatus of claim 1 wherein the plurality of memory channels comprises at least 64 memory channels per memory chip of the memory chips.

7. The apparatus of claim 6 wherein the plurality of memory channels comprises at least 128 memory channels per memory chip.

8. The apparatus of claim 1 wherein at least some of the respective power and ground nodes of those of the memory channels on a same one of the memory chips are electrically isolated from one another.

9. An apparatus, comprising:
a memory chip stack comprising memory chips having a first plurality of memory channels, where, non-yielding ones of the memory channels are to be disabled during operation of the memory chip stack, wherein, the first plurality of memory channels have a second plurality of memory banks, where, non-yielding ones of the memory banks within yielding ones of the memory channels are to be disabled during the operation of the memory chip stack; and,
a logic chip, the memory chip stack mounted to the logic chip, the logic chip comprising a decoder with interleaving circuitry, the interleaving circuitry to implement memory address interleaving that does not map host addresses to the non-yielding ones of the memory channels and the non-yielding ones of the memory banks.

10. The apparatus of claim 9 wherein yielding ones of the memory channels are to be disabled so that there is a predetermined number of working memory channels on each of the memory chips.

11. The apparatus of claim 9 wherein yielding ones of the memory banks are to be disabled so that there is a predetermined number of working memory banks in each of the memory channels.

12. The apparatus of claim 9 wherein all yielding ones of the memory channels are to be enabled.

13. The apparatus of claim 12 wherein all yielding banks of the yielded memory channels are to be enabled.

14. The apparatus of claim 9 wherein the plurality of memory channels comprises at least 64 memory channels per memory chip of the memory chips.

15. The apparatus of claim 14 wherein the plurality of memory channels comprises at least 128 memory channels per memory chip.

16. The apparatus of claim 9 wherein at least some of the respective power and ground nodes of those of the memory channels on a same one of the memory chips are electrically isolated from one another.

17. A computing system, comprising:
a memory chip stack comprising memory chips having a first plurality of memory channels, where, non-yielding ones of the memory channels are to be disabled during operation of the memory chip stack, wherein, the first plurality of memory channels have a second plurality of memory banks, where, non-yielding ones of the memory banks within yielding ones of the memory channels are to be disabled during the operation of the memory chip stack; and,
a logic chip, the memory chip stack mounted to the logic chip, the logic chip comprising a decoder with interleaving circuitry, the interleaving circuitry to implement memory address interleaving that does not map host addresses to the non-yielding ones of the memory channels and the non-yielding ones of the memory banks, the logic chip comprising at least one of a general purpose processing core, a graphics processing core, a computational accelerator, a machine learning core, an inference engine core, an image processing core, and an infrastructure processing unit core.

18. The computing system of claim 17 wherein yielding ones of the memory channels are to be disabled so that there is a predetermined number of working memory channels on each of the memory chips.

19. The computing system of claim 17 wherein yielding ones of the memory banks are to be disabled so that there is a predetermined number of working memory banks in each of the memory channels.

20. The computing system of claim 17 wherein all yielding ones of the memory channels are to be enabled.

21. An apparatus, comprising:
a logic chip, a memory chip stack to be mounted to the logic chip, the logic chip comprising a decoder with interleaving circuitry, the interleaving circuitry to implement memory address interleaving that does not map host addresses to non-yielding ones of the memory chip stack's memory channels nor to non-yielding memory banks of yielding ones of the memory chip stack's memory channels, the logic chip comprising at least one of a general purpose processing core, a graphics processing core, a computational accelerator, a machine learning core, an inference engine core, an image processing core, and an infrastructure processing unit core.
